(19) United States
(12) Patent Application Publication
(10) Pub. No.: US 2026/0070839 A1
(43) Pub. Date: Mar. 12, 2026

(54) ETCHING DEVICE AND WINDOW MANUFACTURING METHOD

(71) Applicant: Samsung Display Co., LTD., Yongin-si (KR)

(72) Inventors: KANG DUK CHOI, Yongin-si (KR); DONGHO KIM, Yongin-si (KR); HYUNCHUL KIM, Yongin-si (KR); BYOUNGYUL SHIM, Yongin-si (KR); SEUNGPYO HONG, Yongin-si (KR)

(21) Appl. No.: 19/246,172

(22) Filed: Jun. 23, 2025

(30) Foreign Application Priority Data
Sep. 10, 2024 (KR) 10-2024-0123495

(51) Int. Cl. C03C 15/02; C09K 13/08; G09F 9/30; H10H 29/01

(52) U.S. Cl. CPC C03C 15/02; C09K 13/08; G09F 9/301; H10H 29/036

(57) ABSTRACT

An etching device includes a stage on which a target substrate is disposed, a nozzle which opposes the stage with the target substrate therebetween and injects an etchant toward the stage, and a mask part including a first mask and a second mask and disposed between the target substrate and the nozzle. The mask part operates in one of a first mode and a second mode. In the first mode, the second mask is spaced from the first mask by a first width in a first direction, and in the second mode, the second mask is spaced from the first mask by a second width in the first direction. The second width is greater than the first width.

This application claims priority to Korean Patent Application No. 10-2024-0123495, filed on Sep. 10, 2024, and all the benefits accruing therefrom under 35 U.S.C. § 119, the content of which in its entirety is herein incorporated by reference.

### BACKGROUND

### 1. Field

The disclosure herein relates to an etching device and a method for manufacturing a window, and more particularly, to an etching device capable of manufacturing a foldable window and a method for manufacturing the foldable window.

### 2. Description of the Related Art

Display devices include display areas activated in response to electrical signals. The display devices may detect inputs applied from the outside through the display areas and also display various images to provide information for users. Recently, with the development for display devices having various shapes, particularly study on foldable display devices is actively carried out, and a method for efficiently etching ultra-thin glass (“UTG”) is desired for achieving a foldable characteristic.

### SUMMARY

The disclosure provides an etching device capable of manufacturing a window having a foldable characteristic and with improved reliability.

The disclosure also provides a window manufacturing method capable of manufacturing a window having a foldable characteristic and with improved reliability through a simple process.

An embodiment of the inventive concept provides an etching device including a stage on which a target substrate is disposed, a nozzle which opposes the stage with the target substrate therebetween and injects an etchant toward the stage, and a mask part which includes a first mask and a second mask and is disposed between the target substrate and the nozzle. The mask part operates in one of a first mode and a second mode. In the first mode, the second mask is spaced from the first mask by a first width in a first direction, and in the second mode, the second mask is spaced from the first mask by a second width in the first direction. The second width is greater than the first width.

In an embodiment, the first mask may include a first surface facing the stage, and the second mask may include a second surface facing the stage. A planar area of the first surface may be less than a planar area of the first mask, and a planar area of the second surface may be less than a planar area of the second mask.

In an embodiment, each of the first surface and the second surface may extend in a second direction crossing the first direction.

In an embodiment, the etching device may further include a motor part connected to each of the first mask and the second mask.

In an embodiment, when the first mode is changed to the second mode, the motor part may move the first mask in an opposite direction to the first direction and move the second mask in the first direction at the same time point.

In an embodiment, when the first mode is changed to the second mode, a speed at which the first mask is moved in the opposite direction to the first direction may be about 1400 micrometers per minute to about 1700 micrometers per minute, and a speed at which the second mask is moved in the first direction may be about 1400 micrometers per minute to about 1700 micrometers per minute.

In an embodiment, the first width may be about 1 millimeter (mm) to about 15 mm, and the second width may be more than about 15 mm and about 30 mm or less.

In an embodiment, the etching device may further include an adsorption plate disposed on a first surface of the stage opposite to a second surface of the stage on which the target substrate is disposed, and an adsorption hole overlapping the adsorption plate may be defined in the stage.

In an embodiment, the mask part may include a material which is not dissolved by the etchant.

In an embodiment, the mask part may include rubber.

In an embodiment, the etchant may include a compound including or consisting of fluorine.

In an embodiment, the compound including or consisting of fluorine may include hydrofluoric acid.

In an embodiment, an amount of the compound including or consisting of fluorine may be about 5 wt % to about 20 wt %, based on a total weight of the etchant.

In an embodiment of the inventive concept, a method for manufacturing a window includes a first operation of providing a stage and a target substrate disposed on the stage, a second operation of disposing, on the target substrate, a nozzle disposed on the stage with the target substrate therebetween, and a mask part which includes a first mask and a second mask spaced from the first mask by a first width in a first direction and is disposed between the target substrate and the nozzle, a third operation of providing an etchant on the target substrate through a gap between the first mask and the second mask by the nozzle for a first time period, a fourth operation of providing the etchant on the target substrate through the gap between the first mask and the second mask by the nozzle for a second time period, and moving the first mask at a first speed in an opposite direction to the first direction and moving the second mask at a second speed in the first direction so that the second mask is spaced from the first mask by a second width in the first direction, and a fifth operation of providing deionized water on the target substrate. The second width is greater than the first width.

In an embodiment, in the second operation, the mask part may be directly disposed on the target substrate.

In an embodiment, the first time period may be about 48 seconds to about 72 seconds, and the second time period may be about 3 minutes to about 17 minutes.

In an embodiment, the method for manufacturing the window may further include, between the third operation and the fourth operation, an operation in which the first mask is accelerated to the first speed to move in the opposite direction to the first direction, and the second mask is accelerated to the second speed to move in the first direction.

In an embodiment, the first width may be about 1 mm to about 15 mm, and the second width may be more than about 15 mm and about 30 mm or less.

In an embodiment, the first speed and the second speed may be substantially the same.

In an embodiment, in the fourth operation, the first speed may be about 1400 micrometers per minute to about 1700 micrometers per minute, and the second speed may be about 1400 micrometers per minute to about 1700 micrometers per minute.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1A to 1C are each a perspective view of an embodiment of a display device according to the inventive concept;

FIG. 2 is an exploded perspective view of an embodiment of a display device according to the inventive concept;

FIGS. 3A and 3B are each a cross-sectional view of an electronic device taken along line I-I′ in FIG. 2;

FIG. 4 is a perspective view of an embodiment of an etching device according to the inventive concept;

FIG. 5 is an exploded perspective view of an embodiment of an etching device according to the inventive concept;

FIG. 6 is a cross-sectional view of the etching device taken along line II-II′ in FIG. 4;

FIGS. 7 to 10 are each a cross-sectional view of an embodiment of a portion of an etching device according to the inventive concept;

FIG. 11 is a flowchart of an embodiment of a method for manufacturing a window according to the inventive concept;

FIGS. 12 to 16B are each a view illustrating an embodiment of a portion of a method for manufacturing a window according to the inventive concept;

FIG. 17 is a perspective view of an embodiment of a target substrate according to the inventive concept;

FIG. 18 is a perspective view of an embodiment of a window according to the inventive concept; and

FIG. 19 is a cross-sectional view of the window taken along line III-III′ in FIG. 18.

### DETAILED DESCRIPTION

In the disclosure, it will be understood that when an element (or region, layer, section, etc.) is referred to as being “on”, “connected to” or “coupled to” another element, it may be disposed directly on, connected or coupled to the other element or a third intervening elements may be disposed between the elements.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the disclosure, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concepts and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

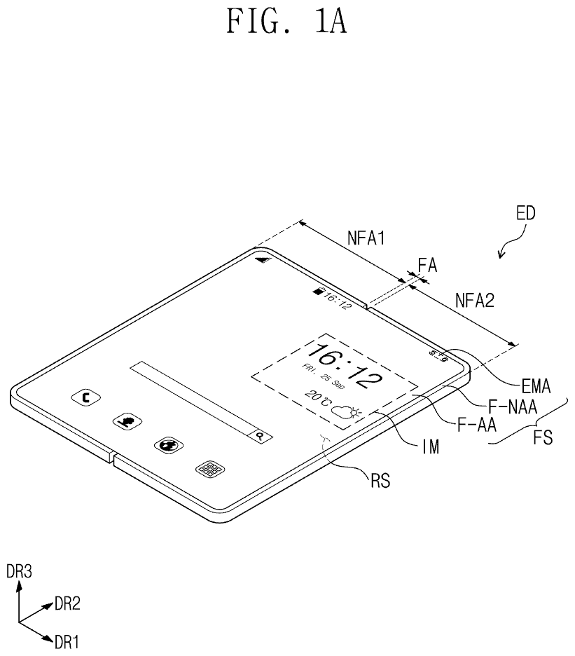

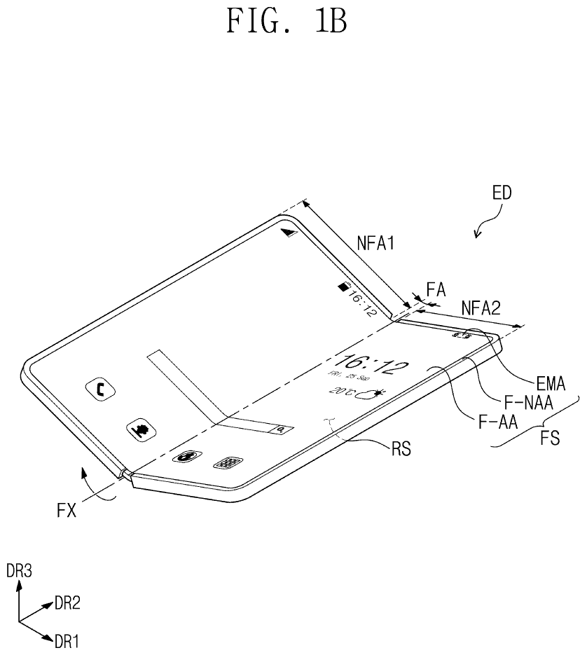

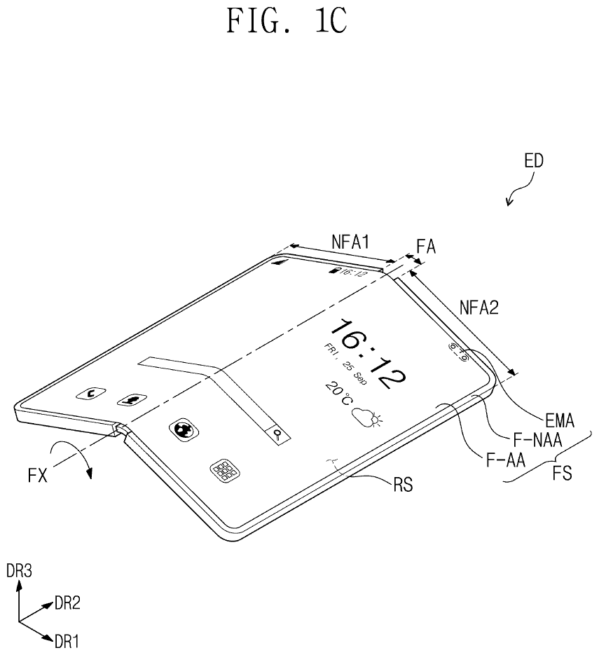

FIGS. 1A to 1C are each a perspective view of an embodiment of a display device according to the inventive concept. FIG. 1A illustrates a spread state, and FIGS. 1B and 1C illustrate folded states.

In FIGS. 1A to 1C, a display device ED is illustrated as a foldable display device which is changed into a folded shape. However, the disclosure is not limited thereto, and the display device ED in an embodiment may be a flexible display device which is changeable in shape by bending or rolling.

The display device ED in an embodiment may include a display surface FS defined by a first direction DR1 and a second direction DR2 crossing the first direction DR1. The display device ED may provide an image IM for a user through the display surface FS. The display device ED in an embodiment may display the image IM toward a third direction DR3 on the display surface FS parallel to each of the first direction DR1 and the second direction DR2.

The display surface FS of the display device ED in an embodiment may include an active area F-AA and a peripheral area F-NAA. The active area F-AA may be an area that is activated in response to an electrical signal. The display device ED in an embodiment may display the image IM through the active area F-AA. In addition, the active area F-AA may detect various types of external inputs. The peripheral area F-NAA is next (adjacent) to the active area F-AA. The peripheral area F-NAA may have a predetermined color. The peripheral area F-NAA may surround the active area F-AA. Accordingly, a shape of the active area F-AA may be substantially defined by the peripheral area F-NAA. However, this is illustrated in an embodiment, and the peripheral area F-NAA may be disposed next (adjacent) to only one side of the active area F-AA or may be omitted. The display device ED in an embodiment of the inventive concept may include active areas having various shapes, and is not limited to a particular embodiment.

The active area F-AA may include a sensing area EMA. Various electronic modules may be disposed in the sensing area EMA. In an embodiment, the electronic modules may include at least one of a camera, a speaker, a light-detecting sensor, or a heat detecting sensor, for example. The sensing area EMA may detect an external subject received through the display surface FS, or provide the outside with a sound signal such as voice, through the display surface FS. The electronic module may include a plurality of components, and is not limited to a particular embodiment.

The sensing area EMA may be surrounded by the active area F-AA and the peripheral area F-NAA. However, the inventive concept is not limited thereto, and the sensing area EMA may be disposed within the active area F-AA, and is not limited to a particular embodiment. FIG. 1 A or the like illustrate one sensing area EMA in an embodiment, but the number of the sensing area EMA is not limited thereto.

The sensing area EMA may be a portion of the active area F-AA. Thus, in the display device ED, the sensing area EMA may also display an image. When the electronic modules disposed in the sensing area EMA are inactivated, the sensing area EMA may serve as a display surface to display a video or the image IM (refer to FIG. 1).

A rear surface RS of the display device ED in an embodiment may be a surface facing the display surface FS. In an embodiment, the rear surface RS may be an outer surface of the display device ED, and a video or the image IM (refer to FIG. 1) may not be displayed thereon. However, the disclosure is not limited thereto, and the rear surface RS may function as a second display surface on which a video or the image IM (refer to FIG. 1) is displayed. Although not separately illustrated, the display device ED in an embodiment may further include a sensing area disposed on the rear surface RS. A camera, a speaker, a light-detecting sensor, or the like may be also disposed in the sensing area disposed on the rear surface RS.

The display device ED may include a folding area FA and non-folding areas NFA1 and NFA2. The display device ED may include a plurality of non-folding areas NFA1 and NFA2. The display device ED in an embodiment may include a first non-folding area NFA1 and a second non-folding area NFA2 which are disposed with the folding area FA therebetween. FIGS. 1A to 1C illustrate an embodiment of the display device ED including one folding area FA. However, the disclosure is not limited thereto, and a plurality of folding areas may be defined in the display device ED. However, the disclosure is not limited thereto. In an embodiment, the display device ED in an embodiment may be folded around a plurality of folding axes to be folded so that portions of the display surface FS face each other, and the number of the folding axes and accordingly the number of the non-folding areas are not particularly limited, for example.

Referring to FIGS. 1B and 1C, the display device ED in an embodiment may be folded around a folding axis FX extending in one direction. The folding axis FX illustrated in FIGS. 1B and 1C may be a virtual axis extending in the second direction DR2, and the folding axis FX may be parallel to a long-side direction of the display device ED. However, the disclosure is not limited thereto, and the extension direction of the folding axis FX is not limited to the second direction DR2.

The folding axis FX may extend on the display surface FS in the second direction DR2, or extend below the rear surface RS in the second direction DR2. Referring to FIG. 1B, in an embodiment, the first non-folding area NFA1 and the second non-folding area NFA2 may face each other, and the display device ED may be in-folded so that the display surface FS is not exposed to the outside. Referring to FIG. 1C, the display device ED in an embodiment may be folded around the folding axis FX and changed into an out-folded state in which one area, which overlaps the first non-folding area NFA1, of the rear surface RS and a remaining (the other) area, which overlaps the second non-folding area NFA2, of the rear surface RS face each other.

In an embodiment, the display device ED may be provided to repeat an operation from a spreading operation to an in-folding or out-folding operation, or vice versa, but the disclosure is not limited thereto. In an embodiment, the display device ED may be provided so as to select one operation from the spreading operation, the in-folding operation, and the out-folding operation.

FIGS. 1A to 1C illustrate the display device ED folded around the folding axis FX parallel to a long side of the display device ED. However, the disclosure is not limited thereto, and the display device in an embodiment may be folded around a folding axis parallel to a short side of the display device.

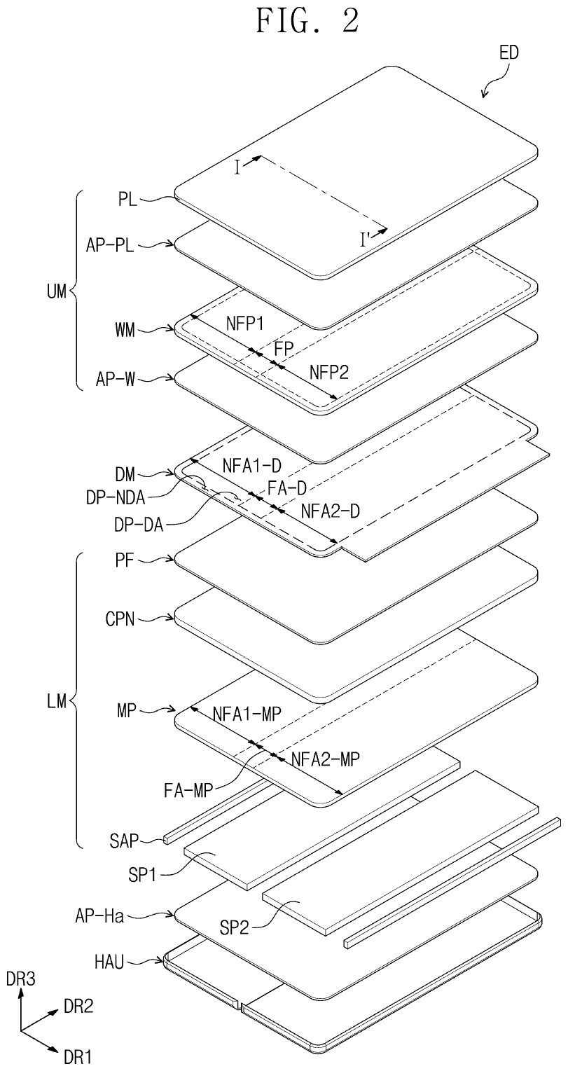

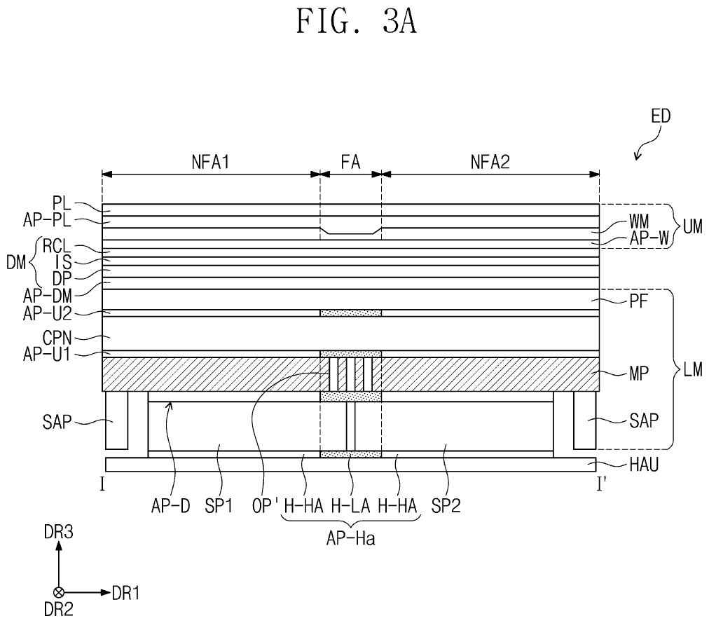

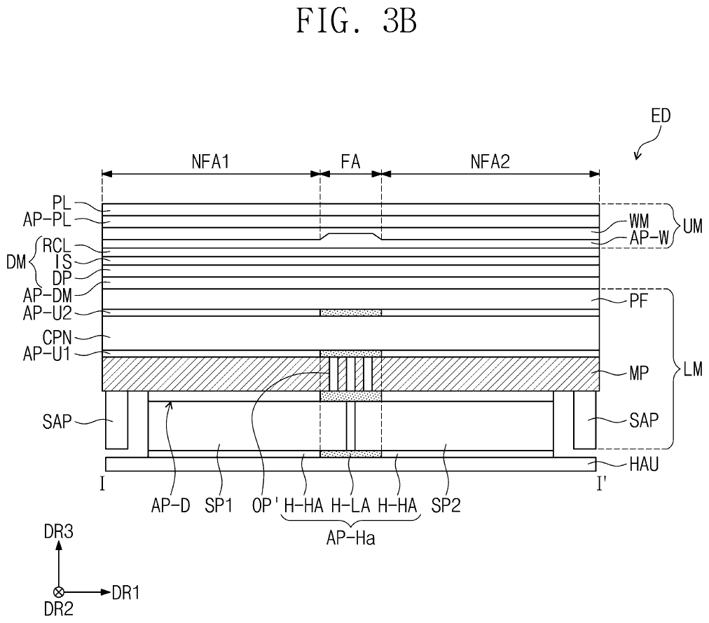

FIG. 2 is an exploded perspective view of an embodiment of a display device. FIG. 3 is a cross-sectional view of a display device. In an embodiment, FIG. 2 illustrates an exploded perspective view of the display device in an embodiment illustrated in FIG. 1A. FIGS. 3A and 3B are each a cross-sectional view illustrating a portion corresponding to line I-I′ in FIG. 2. Unlike the display device illustrated in FIG. 3A, the display device illustrated in FIG. 3B has a concave pattern on a bottom surface of a window.

Referring to FIGS. 2 to 3B together, a display device ED in an embodiment may include a display module DM, an upper module UM disposed above the display module DM, and a lower module LM disposed below the display module DM. In the disclosure, the upper module UM may be also referred to as a protective member, and the lower module LM may be also referred to as a support member.

The upper module UM may be disposed above the display module DM and function as a protective part which protects the display module DM from an external impact or the like, or an optical part which prevents reflection of external light or increases photo-extraction efficiency, for example.

The upper module UM may include a window WM disposed above the display module DM, a protective layer PL disposed above the window WM, and a protective layer adhesive layer AP-PL disposed between the window WM and the protective layer PL.

The window WM may cover an entirety of the outer side of the display module DM. The window WM may have a shape corresponding to a shape of the display module DM. In the display device ED in an embodiment, the window WM may include an optically transparent insulating material. The window WM may be a glass substrate or a polymer substrate. In an embodiment, the window WM may be a tempered glass substrate that has undergone a strengthening treatment, for example. In the window WM in an embodiment of the inventive concept, a stepped portion between a folding portion FP corresponding to a folding area FA and each of non-folding portions NFP1 and NFP2 corresponding to non-folding areas NFA1 and NFA2 may be provided to contribute to a folding characteristic of the display device ED. The stepped portion between the folding portion FP and each of the non-folding portions NFP1 and NFP2 of the window WM in an embodiment of the inventive concept may be generated as a concave pattern defined in a top surface of the window WM as illustrated in FIG. 3A, or generated as a concave pattern defined in a bottom surface of the window WM as illustrated in FIG. 3B. In the window WM in an embodiment of the inventive concept, a boundary between the folding portion FP and each of the non-folding portions NFP1 and NFP2 may be defined to be gentle, thereby improving a distortion phenomenon which may occur between a display area DP-DA and a non-display area DP-NDA of the display device ED. The detailed shape of the window WM will be described later with reference to FIG. 18.

The upper module UM may further include a window adhesive layer AP-W disposed below the window WM. The window adhesive layer AP-W may be disposed between the display module DM and the window WM. The window adhesive layer AP-W may be an optically clear adhesive film (“OCA”) or an optically clear adhesive resin layer (“OCR”). In embodiment, the window adhesive layer AP-W may be omitted.

In an embodiment, the protective layer PL may be disposed above the window WM and protect the window WM from an external environment. The protective layer PL may be transparent, and even when the protective layer PL is disposed, information on the image IM (refer to FIG. 1) provided from the display module DM may be confirmed. The protective layer PL may be exposed as the uppermost surface of the display device ED, and the protective layer PL may be damaged as the display device ED is used.

The protective layer PL may have optical properties that are a haze value of less than about 1% and a transmittance of about 90% or more in a visible light region. The protective layer PL may include a polymer film. The protective film PL may include the polymer film as a base layer, and further include functional layers such as a hard coating layer, an anti-fingerprint coating layer, and an anti-static coating layer, on the base layer. The protective layer PL used in the display device ED in an embodiment may have flexibility.

The protective layer PL in an embodiment may be a polymer film including at least one polymer resin of polyethylene terephthalate (“PET”), poly(butylene terephthalate) (“PBT”), polyethylene naphthalene (“PEN”), polycarbonate (“PC”), poly(methylmethacrylate) (“PMMA”), polystyrene (“PS”), polyvinylchloride (PVC), polyethersulfone (“PES”), polypropylene (“PP”), polyamide (“PA”), modified polyphenylene ether (“m-PPO”), polyoxymethylene (“POM”), polysulfone (“PSU”), polyphenylene sulfide (“PPS”), polyimide (“PI”), polyethyleneimine (“PEI”), polyether ether ketone (“PEEK”), polyamide imide (“PAI”), polyarylate (“PAR”), or thermoplastic polyurethane (“TPU”).

In an embodiment, the protective layer PL in an embodiment may be a PET film or a TPU film, for example. The protective layer PL may be a PET film with no phase retardation.

In the display device ED in an embodiment, the protective layer adhesive layer AP-PL may be disposed between the window WM and the protective layer PL. The protective layer adhesive layer AP-PL may be an optically clear adhesive layer. The protective layer adhesive layer AP-PL may be attached to the window WM and fix the protective layer PL to the window WM.

The display device ED in an embodiment may include a housing HAU which accommodates the display module DM and the lower module LM. The housing HAU may be coupled to the window WM. In addition, the housing HAU may include a hinge structure for easy folding or bending. The hinge structure may be disposed to correspond to the folding area FA.

The display device ED in an embodiment may include a housing adhesive layer AP-Ha. The housing adhesive layer AP-Ha may function to fix the lower module LM to the housing HAU. The housing adhesive layer AP-Ha may include a folding adhesive portion H-LA corresponding to the folding area FA, and non-folding adhesive portions H-HA corresponding to the non-folding areas NFA1 and NFA2. The housing adhesive layer AP-Ha may be an adhesive member which couples the lower module LM and the housing HAU to each other, and also function as an electromagnetic shielding layer or a heat dissipating layer.

The display module DM included in the display device ED in an embodiment may be a component that generates an image and detects an input applied from the outside. The display module DM in an embodiment may include a display panel DP and an input sensor IS disposed on the display panel DP. The display module DM in an embodiment may further include an optical layer RCL disposed on the input sensor IS.

The display panel DP may be a component that substantially generates an image. The display panel DP may be an emissive display panel, and for example, the display panel DP may be an organic light-emitting display panel, an inorganic light-emitting display panel, a quantum dot display panel, a micro light-emitting diode (“LED”) display panel, or a nano LED display panel. The display panel DP may be also referred to as a display layer.

The input sensor IS may be disposed on the display panel DP. The input sensor IS may detect an external input applied from the outside. The external input may be a user's input. The user's input may include various types of external inputs such as part of the user's body, light, heat, pen, or pressure.

The input sensor IS may be formed on the display panel DP through a continuous process. In this case, the input sensor IS may be also referred to as being directly disposed on the display panel DP. The phrase “being directly disposed” may mean that a third component is not disposed between the input sensor IS and the display panel DP. That is, a separate adhesive member may not be disposed between the input sensor IS and the display panel DP. In an alternative embodiment, the input sensor IS may be coupled to the display panel DP through an adhesive member. The adhesive member may include a general adhesive or adhesive agent.

The optical layer RCL may be disposed on the input sensor IS. The optical layer RCL may be an anti-reflective layer that reduces reflectance of external light incident from the outside of the display module DM. The optical layer RCL may be formed on the input sensor IS through a continuous process. The optical layer RCL may include a polarizing plate, or include a color filter layer. In an alternative embodiment, the optical layer RCL may include a pigment, a dye, or the like, and absorb light in a predetermined wavelength range. In a case in which the optical layer RCL includes a color filter layer. the color filter layer may include a plurality of color filters disposed in a predetermined array. In an embodiment, the color filters may be arranged considering emissive colors of pixels included in the display panel DP, for example. The optical layer RCL may further include a division pattern which divides the pixels or the like of the display panel DP. The division pattern may include a black pigment or dye. In an embodiment of the inventive concept, the optical layer RCL may be omitted.

The display module DM in an embodiment may be defined as a display area DP-DA and a non-display area DP-NDA. The display area DP-DA may be defined as an area which emits an image provided from the display module DM.

The non-display area DP-NDA is next (adjacent) to the display area DP-DA. In an embodiment, the non-display area DP-NDA may surround the display area DP-DA, for example. However, this is illustrated in an embodiment, and the non-display area DP-NDA may be defined to have various shapes, and is not limited to a particular embodiment. In an embodiment, the display area DP-DA of the display module DM may correspond to at least a portion of the active area F-AA (refer to FIG. 1A).

In the display device ED in an embodiment, the display module DM may include a folding display portion FA-D and non-folding display portions NFA1-D and NFA2-D. The folding display portion FA-D may be a portion corresponding to the folding area FA (refer to FIG. 1A), and the non-folding display portions NFA1-D and NFA2-D may be portions corresponding to the non-folding areas NFA1 and NFA2 (refer to FIG. 1A).

The folding display portion FA-D may correspond to a portion folded or bent around the folding axis FX (refer to FIG. 1B). The display module DM may include a first non-folding display portion NFA1-D and a second non-folding display portion NFA2-D, and the first non-folding display portion NFA1-D and the second non-folding display portion NFA2-D may be spaced apart from each other with the folding display portion FA-D therebetween.

The display device ED in an embodiment may further include a module adhesive layer AP-DM disposed between the display module DM and the lower module LM. The module adhesive layer AP-DM may be an optically clear adhesive film (“OCA”) or an optically clear adhesive resin layer (“OCR”).

In the display device ED in an embodiment, the lower module LM may include a support plate MP and adhesive layers AP-U1, AP-U2 and AP-D disposed above and below the support plate MP. In an embodiment, the lower module LM may further include at least one of supports SP1 and SP2, a filling part SAP, a module protective layer PF, or a buffer layer CPN. In an embodiment, the display device ED in an embodiment may include the support plate MP disposed below the display module DM, the module protective layer PF and the buffer layer CPN which are disposed between the support plate MP and the display module DM, and the supports SP1 and SP2 and the filling part SAP which are disposed below the support plate MP, for example.

In an embodiment, the support plate MP may be disposed below the display module DM. The support plate MP may include a folding support portion FA-MP and non-folding support portions NFA1-MP and NFA2-MP. In the disclosure, the folding support portion FA-MP may be also referred to as a folding portion, and the non-folding support portions NFA1-MP and NFA2-MP may be also referred to as non-folding portions. A first non-folding folding portion NFA1-MP and a second non-folding portion NFA2-MP of the support plate MP may be spaced apart from each other with the folding portion FA-MP therebetween. The folding portion FA-MP may be a portion corresponding to the folding area FA, and the non-folding portions NFA1-MP and NFA2-MP may be portions corresponding to the non-folding areas NFA1 and NFA2.

In an embodiment, the support plate MP may include a metal material or a polymer material. In an embodiment, the support plate MP may include stainless steel, aluminum, or any alloys thereof. In an alternative embodiment, the support plate MP may include or consist of carbon fiber reinforced plastic (“CFRP”) or the like, for example. However, the disclosure is not limited thereto, and the support plate MP may include at least one of a non-metal material, plastic, glass fiber reinforced plastic, or glass.

A plurality of openings OP′ may be defined in the support plate MP. The openings OP′ may be defined to correspond to the folding area FA.

The module protective layer PF may be disposed between the display module DM and the support plate MP. The module protective layer PF may be a layer which is disposed below the display module DM and protects a rear surface of the display module DM. The module protective layer PF may overlap the entirety of the display module DM. The module protective layer PF may include a polymer material. In an embodiment, the module protective layer PF may be a polyimide film or a polyethylene terephthalate film, for example. However, this is illustrative, and the material of the module protective layer PF is not limited thereto.

The display device ED in an embodiment may include the supports SP1 and SP2 and the filling part SAP. The supports SP1 and SP2 may be portions overlapping most of an area of the display module DM. The filling part SAP may be a portion disposed outside the supports SP1 and SP2 and overlapping an outer edge of the display module DM.

The supports SP1 and SP2 may include a first sub-support SP1 and a second sub-support SP2 which are spaced apart from each other in the first direction DR1. The first sub-support SP1 and the second sub-support SP2 may be spaced apart from each other at a portion corresponding to the folding axis FX (refer to FIG. 1B). The supports SP1 and SP2 may be spaced apart from each other in the folding area FA and provided as the first sub-support SP1 and the second sub-support SP2, thereby improving the folding or bending characteristic of the display device ED. Although not illustrated, the lower module LM may further include a cushion layer (not illustrated) stacked above or below the supports SP1 and SP2. The cushion layer (not illustrated) may include sub-cushion layers separated from each other at a portion corresponding to the folding axis FX (refer to FIG. 1B). A lower adhesive layer, in which adhesion of a portion corresponding to the folding area FA is less than adhesion of a portion corresponding to each of the non-folding areas NFA1 and NFA2, may be further disposed between the supports SP1 and SP2 and the cushion layer (not illustrated).

The cushion layer (not illustrated) may prevent the support plate MP from being pressed or deformed due to an external impact and force. The cushion layer (not illustrated) may include an elastomer such as sponge, foam, or urethane resin. The cushion layer (not illustrated) may include at least one of an acrylic polymer, a urethane-based polymer, a silicon-based polymer, or an imide-based polymer. However, the disclosure is not limited thereto. The cushion layer (not illustrated) may be disposed below the support plate MP or below a lower support plate (not illustrated).

The filling part SAP may be disposed outside the supports SP1 and SP2. The filling part SAP may be disposed between the support plate MP and the housing HAU. The filling part SAP may fill a space between the support plate MP and the housing HAU, and fix the support plate MP.

In the display device ED in an embodiment, the lower module LM may include the buffer layer CPN. The buffer layer CPN may serve as a thickness compensating layer which compensates a thickness of the lower side of the display module DM, or a support layer which supports the display module DM. Unlike the illustrated embodiment, the buffer layer CPN may be omitted in an embodiment.

In the display device ED in an embodiment, a combination of the components included in the lower module LM is not limited to the configuration illustrated or described herein, and the combination may be changed according to the size or shape of the display device ED, or the operation characteristics of the display device ED. In an embodiment, the lower module LM may further include a component such as an additional support plate, cushion member, or adhesive layer, for example.

In the display device ED in an embodiment, the lower module LM may include one or more adhesive layers (also referred to as upper adhesive layers) AP-U1 and AP-U2 disposed above the support plate MP, and at least one module adhesive layer (also referred to as a lower adhesive layer) AP-D disposed below the support plate MP.

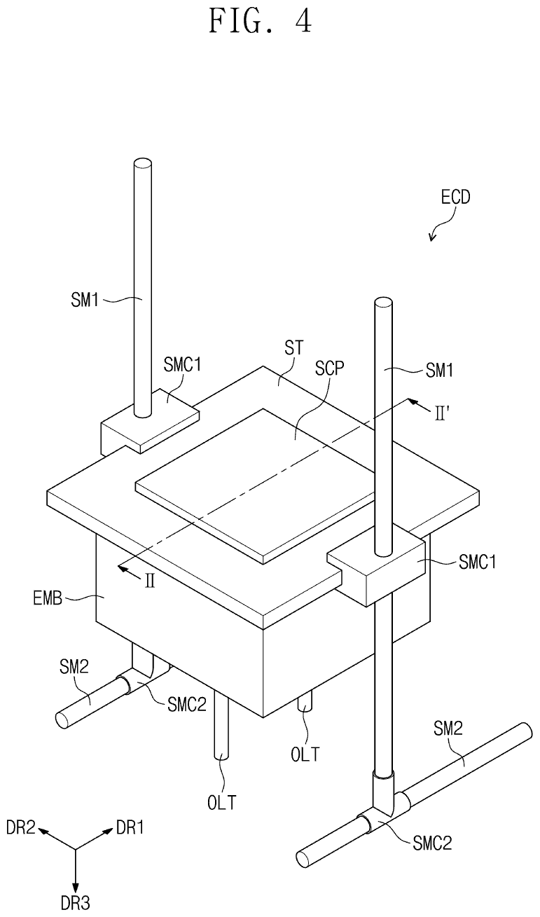

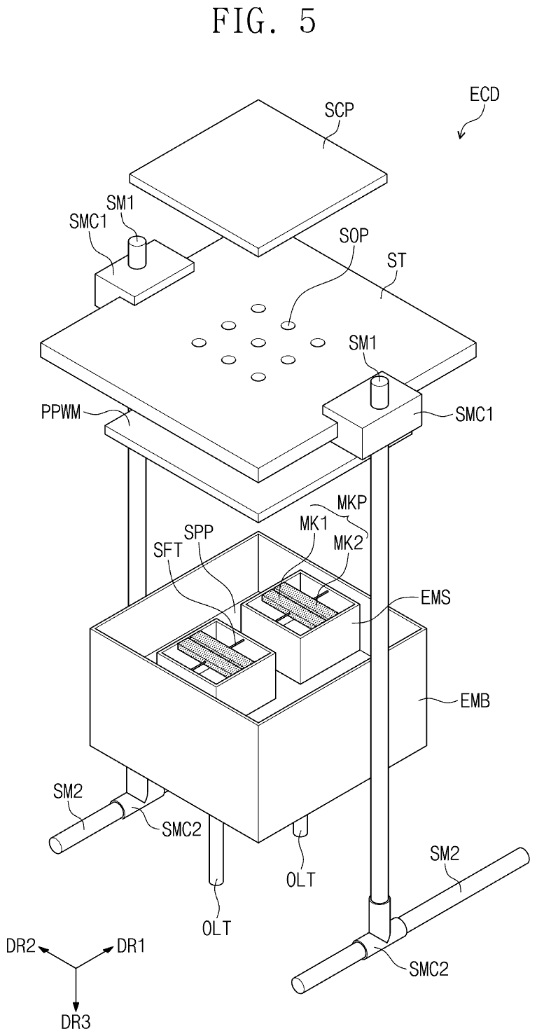

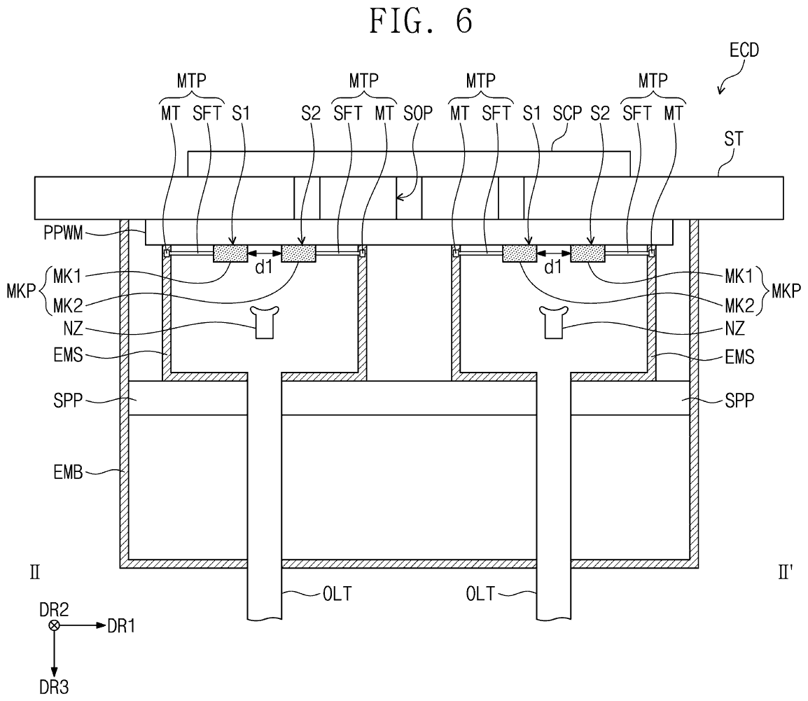

FIG. 4 is a perspective view of an embodiment of an etching device according to the inventive concept. FIG. 5 is an exploded perspective view of an embodiment of an etching device according to the inventive concept. FIG. 6 is a cross-sectional view of the etching device taken along line II-II′ in FIG. 4. FIG. 6 illustrates a case in which a mask part MKP is provided in plural.

Referring to FIGS. 4 to 6 together, an etching device ECD in an embodiment of the inventive concept includes a stage ST, a nozzle NZ, and the mask part MKP.

A target substrate PPWM is disposed on the stage ST. The stage ST may provide a base surface to which the target substrate PPWM is fixed. The stage ST may include an acid resistance material. The acid resistance material may include plastic. The stage ST may include or consist of plastic. The stage ST may not be corroded by an etchant to be described later. Unlike the embodiment illustrated in FIG. 5, the stage ST may be large enough for a plurality of target substrates PPWM to be disposed thereon.

An adsorption hole SOP may be defined in the stage ST. The etching device ECD in an embodiment may further include an adsorption plate SCP which is disposed on a first surface (e.g., upper surface in FIG. 6) of the stage ST opposite to a second surface (e.g., lower surface in FIG. 6) of the stage ST and overlaps the adsorption hole SOP. The adsorption plate SCP may maintain an internal air pressure of the adsorption hole SOP to be relatively low and use an air pressure difference from atmospheric pressure so that the target substrate PPWM is fixed onto the stage ST. The adsorption hole SOP may be provided in plural, and when the adsorption plate SCP is provided in plural, the target substrate PPWM may more tightly come into close contact with an upper side of the stage ST.

The etching device ECD in an embodiment may further include a first stage moving rod SM1, a second stage moving rod SM2, a first stage connecting part SMC1, and a second stage connecting part SMC2. The first stage moving rod SM1 may be provided in two, and the two first stage moving rods SM1 may be disposed spaced apart from each other in the first direction DR1 with the stage ST therebetween. The first stage connecting part SMC1 may be provided in two, and the two first stage connecting parts SMC1 may be coupled to the first stage moving rods SM1 in a one-to-one manner and move in the third direction DR3 or in an opposite direction to the third direction DR3. The stage ST may be coupled to the first stage connecting part SMC1 and move in the third direction DR3 or in the opposite direction to the third direction DR3.

The second stage moving rod SM2 may be provided in two, and the two second stage moving rods SM2 may be disposed spaced apart from each other in the second direction DR2 with the stage ST therebetween. The second stage connecting part SMC2 may be provided in two, and the two second stage connecting parts SMC2 may be coupled to the first stage moving rods SM1 in a one-to-one manner and move in the first direction DR1 or in an opposite direction to the first direction DR1. The first stage moving rod SM1 may be coupled to the second stage connecting part SMC2 and move in the first direction DR1 or in the opposite direction to the first direction DR1. As the stage ST moves in the first direction DR1 or in the opposite direction to the first direction DR1, the nozzle NZ to be described later may apply an etchant onto more areas of the target substrate PPWM, and as a result, more windows WM (refer to FIG. 3A) may be produced.

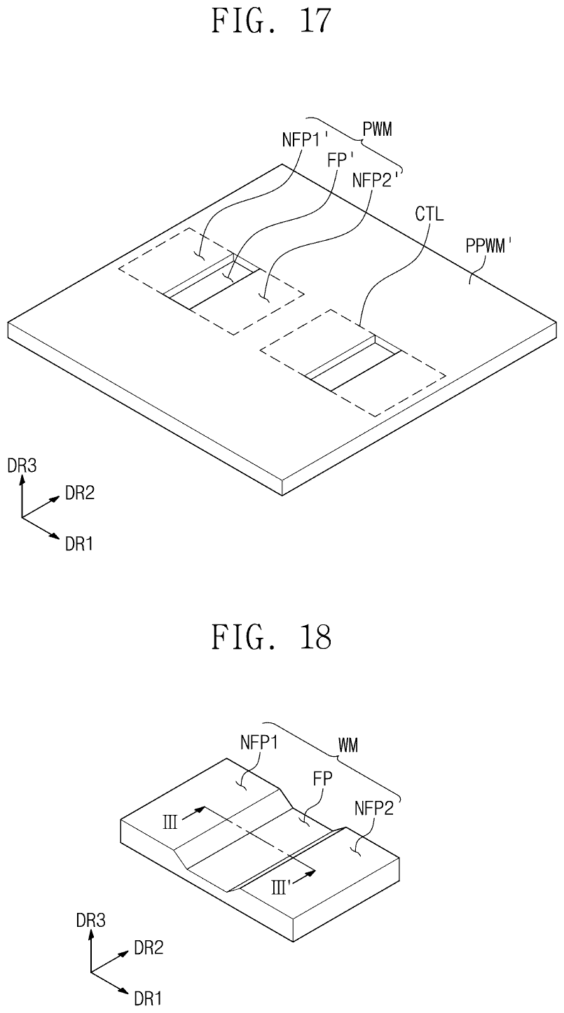

When the etching device ECD in an embodiment of the inventive concept is used, a portion of the target substrate PPWM may be etched to form the window WM (refer to FIG. 3A) described above. The target substrate PPWM may include a plurality of preliminary windows PWM (refer to FIG. 17). A user may cut a portion of the target substrate PPWM, the portion of which has been etched according to the use of the etching device ECD in an embodiment of the inventive concept, thereby producing the plurality of windows WM (refer to FIG. 3A) through one process.

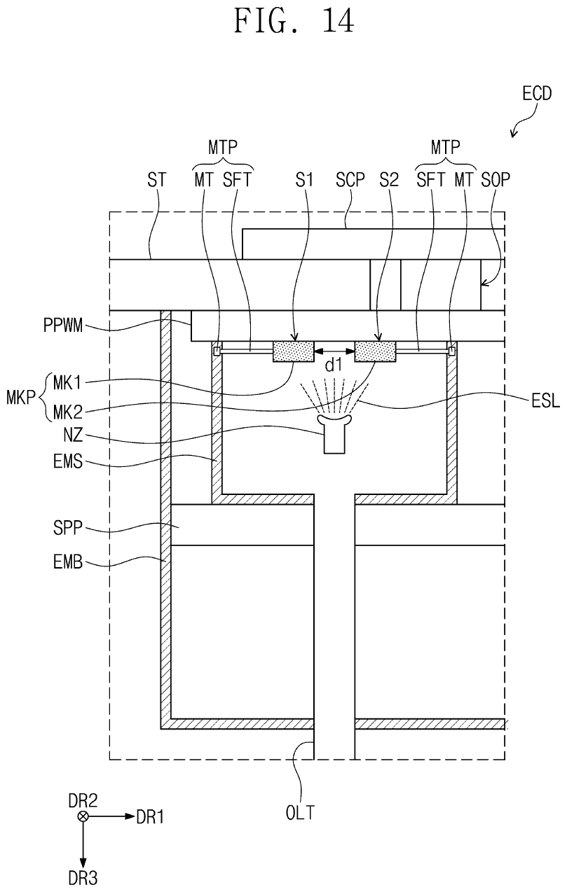

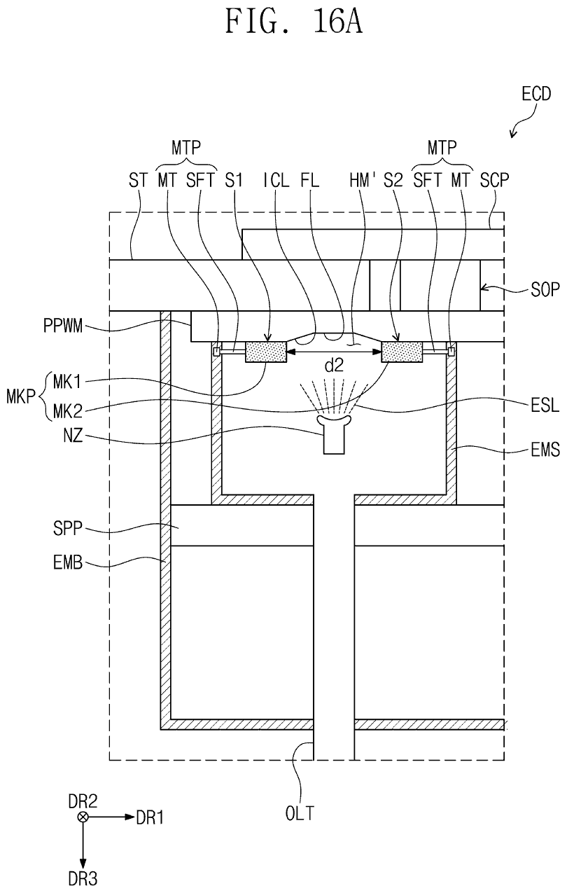

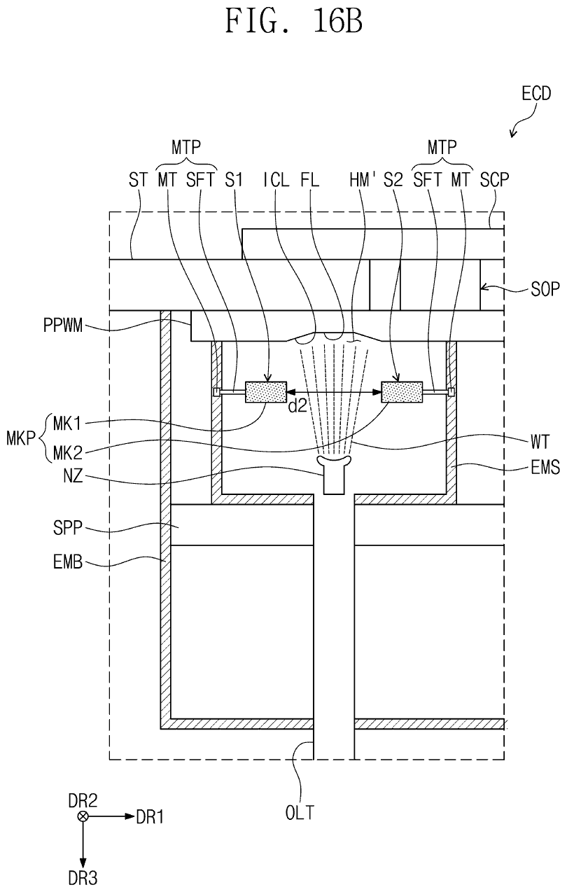

The nozzle NZ may oppose the stage ST with the target substrate PPWM therebetween, and inject an etchant ESL (refer to FIG. 14) or deionized water WT (refer to FIG. 16B) toward the stage ST. The nozzle NZ may include a solenoid valve. The nozzle NZ may selectively inject the etchant ESL (refer to FIG. 14) or the deionized water WT (refer to FIG. 16B). The nozzle NZ may move in the second direction DR2 or in an opposite direction to the second direction DR2. The nozzle NZ may be provided in plural.

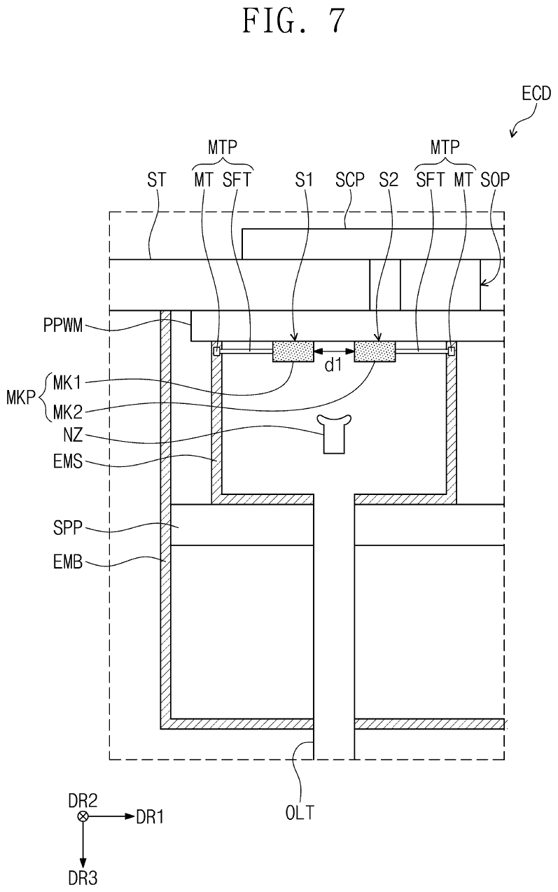

The mask part MKP is disposed between the target substrate PPWM and the nozzle NZ (refer to FIG. 7). The mask part MKP may include a material which is not dissolved by the etchant ESL (refer to FIG. 14). The mask part MKP may include rubber. A pressure may be applied onto the target substrate PPWM so that the mask part MKP is disposed to be in close contact with the target substrate PPWM. The mask part MKP includes a first mask MK1 and a second mask MK2. The first mask MK1 may include a first surface S1 facing the stage ST, and the second mask MK2 may include a second surface S2 facing the stage ST. The first surface S1 or the second surface S2 may be opposite to the stage ST with reference to the target substrate PPWM. The first mask MK1 may be in direct contact with the target substrate PPWM through the first surface S1. The second mask MK2 may be in direct contact with the target substrate PPWM through the second surface S2. The detailed configuration and operations of the mask part MKP will be described with reference to FIGS. 7 to 10.

The etching device ECD in an embodiment may further include a motor part MTP, an etching mask container EMB, a support substrate SPP, an etching mask sealing machine EMS, and an outlet OLT.

The motor part MTP may include a motor MT and a shaft SFT. The motor part MTP may be connected to the mask part MKP. The motor MT may be connected to the shaft SFT to rotate the shaft SFT. The motor MT may include a driving motor and a reduction gear. The driving motor may be directly connected to the shaft SFT to rotate the shaft SFT. The reduction gear may control a speed at which the shaft SFT rotates. A user may control each of the first mask MK1 and the second mask MK2 through an operation of the motor MT in terms of whether to be moved, a moving direction, and a moving speed. The shaft SFT may be directly coupled to each of the motor MT and the mask part MKP. A thread may be provided on the shaft SFT, and a thread groove corresponding to the thread of the shaft SFT may be defined in each of the first mask MK1 and the second mask MK2. When the shaft SFT is rotated by the motor MT, each of the first mask MK1 and the second mask MK2 may move in the first direction DR1 or the opposite direction to the first direction DR1.

The etching mask container EMB may be disposed on the stage ST. The etching mask container EMB may be in direct contact with the stage ST. The etching mask container EMB may include a quadrangular, e.g., rectangular parallelepiped shape which has an opened top surface and is empty inside. The shaft SFT, the mask part MKP, the support substrate SPP, and the etching mask sealing machine EMS may be disposed inside the etching mask container EMB. A planar area of the etching mask container EMB may be greater than a planar area of the target substrate PPWM. The etching mask container EMB may include a material which is not dissolved by the etchant. In an embodiment, the etching mask container EMB may include plastic, for example. The etching mask container EMB may be in direct contact with the stage ST and prevent the etchant from leaking out of the etching mask container EMB during a window manufacture process.

The support substrate SPP may be disposed inside the etching mask container EMB. The support substrate SPP may be in direct contact with an inner surface of the etching mask container EMB. The support substrate SPP may support the etching mask sealing machine EMS to be described later.

The etching mask sealing machine EMS may be disposed inside the etching mask container EMB. The etching mask sealing machine EMS may be disposed between the support substrate SPP and the stage ST. The etching mask sealing machine EMS may be directly disposed on the support substrate SPP. The etching mask sealing machine EMS may be in direct contact with the target substrate PPWM during the window manufacture process. The mask part MKP and the nozzle NZ may be disposed inside the etching mask sealing machine EMS. The etching mask sealing machine EMS may prevent the etchant from leaking out of the etching mask sealing machine EMS during the window manufacture process, thereby preventing a portion other than a portion, which is intended to be etched, of the target substrate PPWM from being etched. FIGS. 5 and 6 each illustrate an embodiment in which the etching mask sealing machine EMS is two in number, but the etching mask sealing machine EMS to be provided may be less or more than two in number. In an embodiment, eight etching mask sealing machines EMS may be provided, for example.

The outlet OLT may pass through the etching mask container EMB, the support substrate SPP, and the etching mask sealing machine EMS. The inside of the etching mask sealing machine EMS may be connected to the outside through the outlet OLT. The outlet OLT may include a material which is not dissolved by the etchant. In an embodiment, the outlet OLT may include plastic, for example. The outlet OLT may provide a passage through which, during the window manufacture process, the etchant provided through the nozzle NZ is discharged to the outside of the etching mask sealing machine EMS. At least one outlet OLT may be provided for one etching mask sealing machine EMS.

Hereinafter, a first mode and a second mode of a mask part MKP will be described with reference to FIGS. 7 to 10. The same/similar components as/to those described with reference to FIGS. 4 to 6 will not be described in detail.

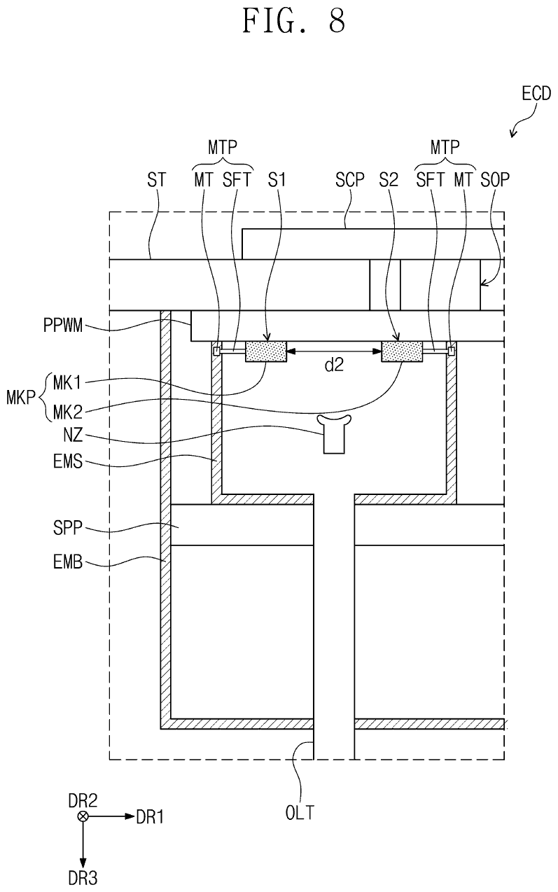

FIGS. 7 to 10 are each a cross-sectional view of an embodiment of a portion of an etching device according to the inventive concept. FIGS. 7 to 10 are each an enlarged view illustrating an embodiment of a portion of a cross-section of the etching device according to the inventive concept. FIG. 7 illustrates a state in which the mask part MKP operates in the first mode, and FIG. 8 illustrates a state in which the mask part MKP operates in the second mode. Compared to FIGS. 7 and 8, FIGS. 9 and 10 each illustrate an embodiment in which an etching device ECD includes a mask part MKP′ having a smaller area to contact a target substrate PPWM.

Referring to FIGS. 7 and 8 together, the mask part MKP operates in one of the first mode and the second mode. In the first mode, a second mask MK2 is spaced from a first mask MK1 by a first width d1 in the first direction DR1. In the second mode, the second mask MK2 is spaced from the first mask MK1 by a second width d2 in the first direction DR1. The second width d2 is greater than the first width d1. The first width d1 may be about 1 millimeter (mm) to about 15 mm. The second width d2 may be more than about 15 mm and about 30 mm or less. In an embodiment, the first width d1 may be about 12 mm, and the second width d2 may be about 25 mm, for example.

When the mask part MKP operates in the second mode from the first mode, the first mask MK1 may move by about 1400 micrometers per minute to about 1700 micrometers per minute in an opposite direction to the first direction DR1, and the second mask MK2 may move by about 1400 micrometers per minute to about 1700 micrometers per minute in the first direction DR1. The first mask MK1 and the second mask MK2 may move at the same time point. In an embodiment, the first mask MK1 may move at a speed of about 1625 micrometers per minute in the opposite direction to the first direction DR1, and the second mask MK2 may move at a speed of about 1625 micrometers per minute in the first direction DR1, for example.

In the etching device ECD in an embodiment of the inventive concept, in a process in which an etchant injected through a nozzle NZ is provided on the target substrate PPWM through a gap between the first mask MK1 and the second mask MK2 and a portion of a top surface of the target substrate PPWM is etched, when the mask part MKP is changed in mode from the first mode to the second mode, an area at which the etchant contacts the top surface of the target substrate PPWM may gradually increase. When the area at which the etchant contacts the top surface of the target substrate PPWM gradually increases, the target substrate PPWM may have a shape in which the etched portion is in the form of a gently curved surface. As a result, in the window WM (refer to FIG. 2), the boundary between the folding portion FP (refer to FIG. 2) and each of the non-folding portions NFP1 and NFP2 (refer to FIG. 2) may be defined to be gentle, thereby improving the distortion phenomenon which may occur between the display area DP-DA (refer to FIG. 2) and the non-display area DP-NDA (refer to FIG. 2) of the display device ED (refer to FIG. 2).

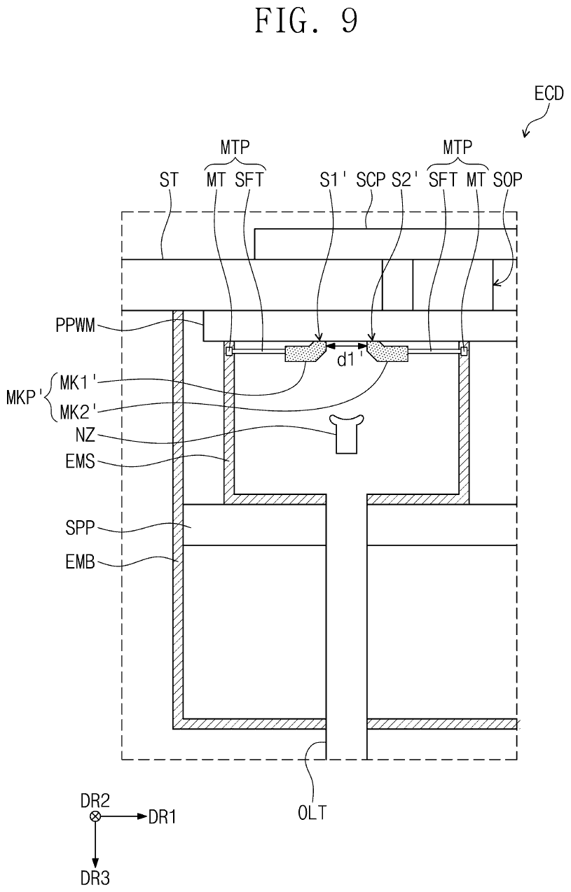

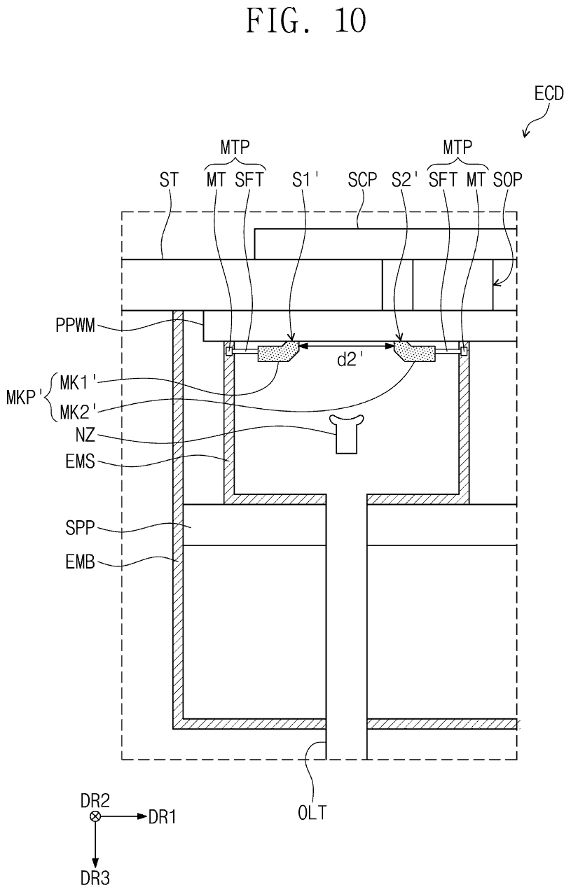

Referring to FIGS. 9 and 10 together, a first mask MK1′ may include a first surface S1′ facing a stage ST, and a second mask MK2′ may include a second surface S2′ facing the stage ST. The first surface S1′ and the second surface S2′ may each extend in the second direction DR2. A planar area of the first surface S1′ may be less than a planar area of the first mask MK1′. A planar area of the second surface S2′ may be less than a planar area of the second mask MK2′. In the area of each of the first surface S1′ and the second surface S2′, the first mask MK1′ and the second mask MK2′ may each have a relatively small area to contact the target substrate PPWM compared to the first mask MK1 and the second mask MK2 illustrated in FIGS. 7 and 8, thereby easily performing a change between the first mode and the second mode. In an embodiment, in the second mode, the second mask MK2 is spaced from the first mask MK1 by a second width d2′ in the first direction DR1.

Hereinafter, a method for manufacturing a window using the above-described etching device in an embodiment of the inventive concept will be described, and the same/similar components as/to those described with reference to FIGS. 1A to 10 will not be described in detail.

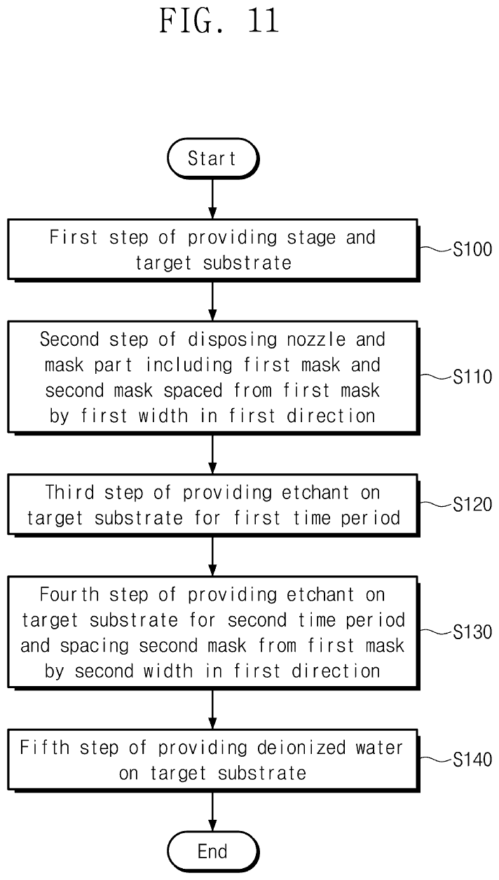

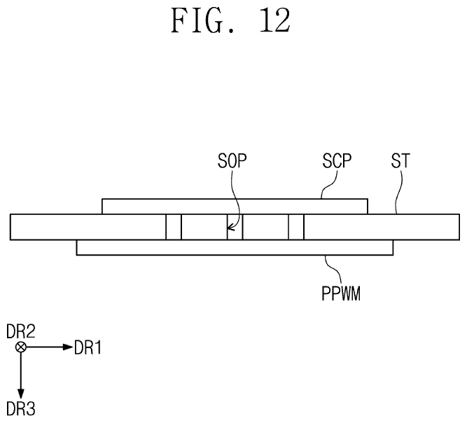

FIG. 11 is a flowchart of an embodiment of the method for manufacturing the window according to the inventive concept. FIGS. 12 to 16B are each a view illustrating an embodiment of a portion of the method for manufacturing the window according to the inventive concept.

Referring to FIG. 11, the method for manufacturing the window in an embodiment of the inventive concept includes a first operation of providing a stage and a target substrate (S100), a second operation of disposing a nozzle, and a mask part including a first mask and a second mask spaced from the first mask by a first width in the first direction (S110), a third operation of providing an etchant on the target substrate for a first time period (S120), a fourth operation of providing the etchant on the target substrate for a second time period and spacing the second mask from the first mask by a second width in the first direction (S130), and a fifth operation of providing deionized water on the target substrate (S140).

Referring to FIG. 12, in the first operation, a target substrate PPWM is disposed on a stage ST. The target substrate PPWM may be directly disposed on the stage ST. The operation of providing the stage ST and the target substrate PPWM may include an operation of providing an adsorption plate SCP disposed on the first surface of the stage ST. The target substrate PPWM may be disposed to overlap an adsorption hole SOP of the stage ST. The target substrate PPWM may be fixed to the stage ST through the adsorption plate SCP.

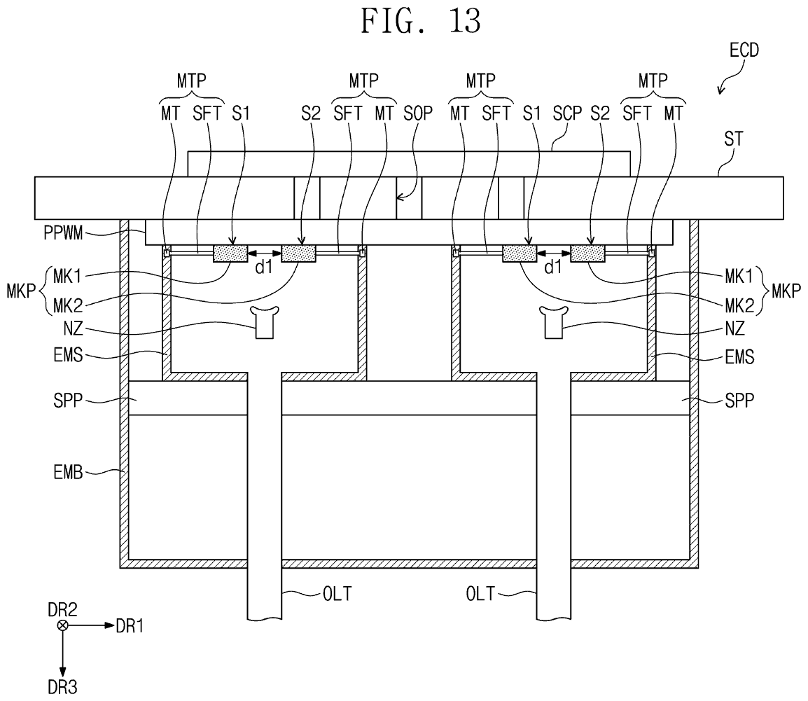

Referring to FIG. 13, in the second operation, a nozzle NZ opposes the stage ST with the target substrate PPWM therebetween. A mask part MKP is disposed between the target substrate PPWM and the nozzle NZ. The mask part MKP may be directly disposed on the target substrate PPWM. The mask part MKP includes a first mask MK1, and a second mask MK2 spaced from the first mask MK1 by a first width d1 in the first direction DR1. The first mask MK1 and the second mask MK2 may contact the target substrate PPWM through a first surface S1 and a second surface S2, respectively. Unlike the illustrated embodiment, the first mask MK1 and the second mask MK2, like the first mask MK1′ and the second mask MK2′ illustrated in FIGS. 9 and 10, may have smaller areas to contact the target substrate PPWM than planar areas of the first mask MK1 and the second mask MK2, respectively. The second operation may further include an operation of providing a motor part MTP, an etching mask container EMB, a support substrate SPP, an etching mask sealing machine EMS, and an outlet OLT.

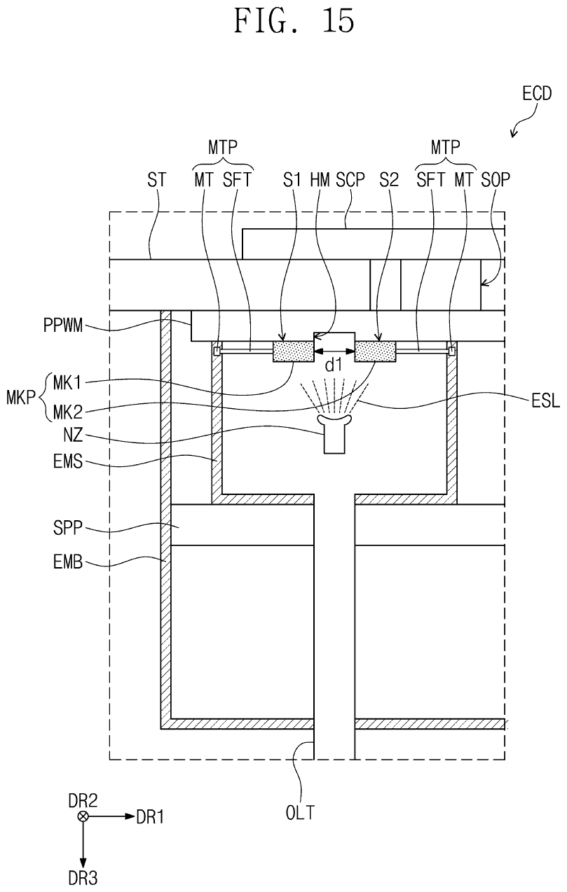

Referring to FIGS. 14 and 15 together, in the third operation, an etchant ESL is provided on the target substrate PPWM through a gap between the first mask MK1 and the second mask MK2 by the nozzle NZ for the first time period. A pressure directed in an opposite direction to the third direction DR3 may be applied onto the target substrate PPWM, thereby bringing each of the first mask MK1 and the second mask MK2 into close contact with an upper side of the target substrate PPWM, and preventing the etchant ESL from being beyond the gap between the first mask MK1 and the second mask MK2. The first time period may be about 48 seconds to about 72 seconds. In an embodiment, the first time period may be about 60 seconds, for example. The etchant ESL may include a fluorine-containing compound. The fluorine-containing compound may include hydrofluoric acid. In the etchant ESL, an amount of the fluorine-containing compound may be about 5 wt % to about 20 wt %, based on a total weight of the etchant ESL. In an embodiment, the amount of the fluorine-containing compound may be about 10 wt %, based on the total weight of the etchant ESL, for example. The etchant ESL may etch a portion of the target substrate PPWM so that a groove HM is defined in a top surface of the target substrate PPWM. A depth of the groove HM may be about 8 micrometers (m) to about 12 m. The first time period and the depth of the groove HM may be directly proportional to each other. When the etchant ESL is in continuous contact with the target substrate PPWM, the target substrate PPWM may be etched to a depth of about 10 micrometers per minute.

Referring to FIG. 16A, in the fourth operation, the etchant ESL is provided on the target substrate PPWM through the gap between the first mask MK1 and the second mask MK2 by the nozzle NZ for the second time period. The second time period may be about 3 minutes to about 17 minutes. In an embodiment, the second time period may be about 3 minutes, for example. The first mask MK1 moves at a first speed in the opposite direction to the first direction DR1, and the second mask MK2 moves at a second speed in the first direction DR1 so that the second mask MK2 is spaced from the first mask MK1 by the second width d2 in the first direction DR1. A pressure directed in the opposite direction to the third direction DR3 may be applied onto the target substrate PPWM, thereby bringing each of the first mask MK1 and the second mask MK2 into close contact with the upper side of the target substrate PPWM, and preventing the etchant ESL from being beyond the gap between the first mask MK1 and the second mask MK2. The first speed may be about 1400 micrometers per minute to about 1700 micrometers per minute, and the second speed may be about 1400 micrometers per minute to about 1700 micrometers per minute. In an embodiment, each of the first speed and the second speed may be about 1625 micrometers per minute, for example. The first speed and the second speed may be substantially the same.

The etchant ESL may etch a portion of the target substrate PPWM so that a groove HM′ is defined in a top surface of the target substrate PPWM. The groove HM′ may be defined by a flat surface FL and an inclined surface ICL. The flat surface FL may be a surface parallel to the first direction DR1. The inclined surface ICL may be a surface which connects the flat surface FL to the top surface of the target substrate PPWM, which is not etched. As the first mask MK1 and the second mask MK2 are away from each other, an area at which the etchant ESL contacts the top surface of the target substrate PPWM may gradually increase. Accordingly, a boundary between the flat surface FL and the inclined surface ICL may be curved, thereby improving reliability of the display device.

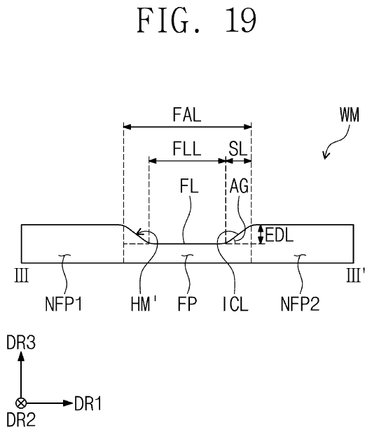

Referring to FIGS. 15 and 16A together, the method for manufacturing the window in an embodiment may further include, between the third operation and the fourth operation, an acceleration operation in which the first mask MK1 is accelerated to the first speed to move in an opposite direction to the first direction DR1 and the second mask MK2 is accelerated to the second speed to move in the first direction DR1. In the acceleration operation, the first mask MK1 may be accelerated from a stop state and accelerated until reaching the first speed in the opposite direction to the first direction DR1, and then move at a constant speed of the first speed in the opposite direction to the first direction. In the acceleration operation, the second mask MK2 may be accelerated from a stop state and accelerated until reaching the second speed in the first direction DR1, and then move at a constant speed of the second speed in the first direction DR1. The boundary between the flat surface FL and the inclined surface ICL, which will be described later, may be formed different according to a degree of acceleration of the first mask MK1 and the second mask MK2. In an embodiment, when the degree of acceleration of the first mask MK1 and the second mask MK2 is small, a boundary between a flat surface FL (refer to FIG. 19) and an inclined surface ICL (refer to FIG. 19) may be curved, for example, thereby improving the reliability of the display device, for example.

Referring to FIG. 16B, in the fifth operation, the nozzle NZ provides deionized water WT onto the target substrate PPWM. The deionized water WT may remove the provided etchant ESL (refer to FIG. 16A) remaining on the target substrate PPWM, thereby preventing the target substrate PPWM from being excessively etched. In the fifth operation, the mask part MKP may be spaced apart from the target substrate PPWM. In the fifth operation, the mask part MKP may be spaced apart from the target substrate PPWM and the deionized water WT may be provided on the target substrate PPWM at the same time point, or alternatively, the deionized water WT may be provided on the target substrate PPWM after the mask part MKP is spaced apart from the target substrate PPWM. Unlike a typical method for manufacturing a window, the method for manufacturing the window in an embodiment may perform the etching process and the cleaning process sequentially, thereby improving efficiency in process.

The method for manufacturing the window in an embodiment may further include, after the fifth operation, an operation of injecting air into the adsorption hole SOP to separate the stage ST and the target substrate PPWM from each other.

FIG. 17 is a perspective view of an embodiment of a target substrate according to the inventive concept. FIG. 18 is a perspective view of an embodiment of a window according to the inventive concept. FIG. 19 is a cross-sectional view of the window taken along line III-III′ in FIG. 18. FIG. 18 illustrates a window WM obtained by cutting a target substrate PPWM′ along a cutting line CTL illustrated in FIG. 17.

Referring FIG. 17, the target substrate PPWM′ formed by the method for manufacturing the window in an embodiment of the inventive concept may include a preliminary window PWM including a preliminary first non-folding portion NFP1′, a preliminary folding portion FP′, and a preliminary second non-folding portion NFP2′. Two preliminary windows PWM are illustrated in an embodiment, but the preliminary windows PWM may be more or less than two in number. In an embodiment, the target substrate PPWM′ may include eight preliminary windows PWM, for example. The preliminary window PWM may be separated from the remaining portion of the target substrate PPWM′ on the basis of the cutting line CTL.

Referring to FIGS. 18 and 19 together, the method for manufacturing the window in an embodiment may further include an operation of performing cutting along the cutting line CTL (refer to FIG. 17) to form a window WM. The window WM may include a first non-folding portion NFP1, a folding portion FP, and a second non-folding portion NFP2. A groove HM′ may be defined in the window WM. The groove HM′ may be defined by a flat surface FL and an inclined surface ICL. An angle AG defined between a virtual plane including the flat surface FL and the inclined surface ICL may be about 0.4 degrees to about 1.6 degrees. A width FLL of the flat surface FL in the first direction DR1 may be about 1 mm to about 15 mm. In an embodiment, the width FLL of the flat surface FL in the first direction DR1 may be about 12 mm, for example. A width SL of the inclined surface ICL in the first direction DR1 may be about 5.7 mm to about 6.5 mm. A sum FAL of the width FLL of the flat surface FL in the first direction DR1 and the width SL of the inclined surface ICL in the first direction DR1 may be more than about 15 mm and about 30 mm or less. An etch depth EDL may be defined as a height difference between the flat surface FL and each of the non-folding portions NFP1 and NFP2. The etch depth EDL may be about 40 micrometers to about 175 micrometers.

A method for manufacturing a window by an etching device in an embodiment of the inventive concept may include a first operation of providing a stage and a target substrate, a second operation of disposing a nozzle and a mask part including a first mask and a second mask spaced from the first mask by a first width in the first direction, a third operation of providing an etchant on the target substrate for a first time period, and a fourth operation of providing the etchant on the target substrate for a second time period and spacing the second mask from the first mask by a second width in the first direction so that, as an area at which the etchant is contact with a top surface of the target substrate gradually increases, the target substrate is formed to have a shape in which an etched portion is in the form of a gently curved surface. As a result, a boundary between a folding portion and a non-folding portion of the window may be gentle, thereby improving a distortion phenomenon which may occur between a display area and a non-display area of the display device.

The etching device in the embodiment of the inventive concept may use the mask movable in the one direction and in the opposite direction to the one direction, thereby manufacturing the window having the foldable characteristic and with the improved reliability through the simple process.

In addition, the method for manufacturing the window in the embodiment of the inventive concept may use the mask movable in the one direction and in the opposite direction to the one direction to manufacture the window having the foldable characteristic and with the improved reliability through the simple process, thereby improving the process difficulty.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the technical scope of the inventive concept is not limited to the contents described in the detailed description of the specification, but should be determined by the claims.

What is claimed is:

1. An etching device which etches a target substrate, the etching device comprising:
a stage on which the target substrate is disposed;
a nozzle opposing the stage with the target substrate therebetween and configured to inject an etchant toward the stage; and
a mask part disposed between the target substrate and the nozzle, the mask part comprising:
a first mask; and
a second mask,
wherein the mask part operates in one of a first mode and a second mode,
wherein, in the first mode, the second mask is spaced from the first mask by a first width in a first direction,
in the second mode, the second mask is spaced from the first mask by a second width in the first direction, and
wherein the second width is greater than the first width.

2. The etching device of claim 1, wherein the first mask comprises a first surface facing the stage, and
the second mask comprises a second surface facing the stage,
wherein a planar area of the first surface is less than a planar area of the first mask, and
a planar area of the second surface is less than a planar area of the second mask.

3. The etching device of claim 2, wherein each of the first surface and the second surface extends in a second direction crossing the first direction.

4. The etching device of claim 1, further comprising a motor part connected to each of the first mask and the second mask.

5. The etching device of claim 4, wherein, when the first mode is changed to the second mode, the motor part moves the first mask in an opposite direction to the first direction and moves the second mask in the first direction at a same time point.

6. The etching device of claim 5, wherein, when the first mode is changed to the second mode, a speed at which the first mask is moved in the opposite direction to the first direction is about 1400 micrometers per minute to about 1700 micrometers per minute, and a speed at which the second mask is moved in the first direction is about 1400 micrometers per minute to about 1700 micrometers per minute.

7. The etching device of claim 1, wherein the first width is about 1 millimeter to about 15 millimeters, and the second width is more than about 15 millimeters and about 30 millimeters or less.

8. The etching device of claim 1, further comprising an adsorption plate disposed on a first surface of the stage opposite to a second surface of the stage on which the target substrate is disposed,
wherein an adsorption hole overlapping the adsorption plate is defined in the stage.

9. The etching device of claim 1, wherein the mask part comprises a material which is not dissolved by the etchant.

10. The etching device of claim 1, wherein the mask part comprises rubber.

11. The etching device of claim 1, wherein the etchant comprises a fluorine-containing compound.

12. The etching device of claim 11, wherein the fluorine-containing compound comprises hydrofluoric acid.

13. The etching device of claim 11, wherein an amount of the fluorine-containing compound is about 5 wt % to about 20 wt %, based on a total weight of the etchant.

14. A method for manufacturing a window from a target substrate, the method comprising:
providing a stage and the target substrate disposed on the stage;
disposing, on the target substrate, a nozzle opposing the stage with the target substrate therebetween, and a mask part which comprises a first mask and a second mask spaced from the first mask by a first width in a first direction and is disposed between the target substrate and the nozzle;
providing an etchant on the target substrate through a gap between the first mask and the second mask by the nozzle for a first time period;
providing the etchant on the target substrate through the gap between the first mask and the second mask by the nozzle for a second time period, and moving the first mask at a first speed in an opposite direction to the first direction and moving the second mask at a second speed in the first direction so that the second mask is spaced from the first mask by a second width in the first direction; and
providing deionized water on the target substrate,
wherein the second width is greater than the first width.

15. The method of claim 14, wherein, in the disposing the nozzle, the mask part is directly disposed on the target substrate.

16. The method of claim 14, wherein the first time period is about 48 seconds to about 72 seconds, and the second time period is about 3 minutes to about 17 minutes.

17. The method of claim 14, further comprising, between the providing the etchant for the first time period and the providing the etchant for the second time period, the first mask is accelerated to the first speed to move in the opposite direction to the first direction, and the second mask is accelerated to the second speed to move in the first direction.

18. The method of claim 14, wherein the first width is about 1 millimeter to about 15 millimeters, and the second width is more than about 15 millimeters and about 30 millimeters or less.

19. The method of claim 14, wherein the first speed and the second speed are substantially identical to each other.

20. The method of claim 14, wherein, in the providing the etchant for the second time period, the first speed is about 1400 micrometers per minute to about 1700 micrometers per minute, and the second speed is about 1400 micrometers per minute to about 1700 micrometers per minute.
